(19) United States
(12) Patent Application Publication
(10) Pub. No.: US 2011/0001245 A1
(43) Pub. Date: Jan. 6, 2011

(54) SEMICONDUCTOR DEVICE INCLUDING SEALING FILM FOR ENCAPSULATING SEMICONDUCTOR CHIP AND PROJECTION ELECTRODES AND MANUFACTURING METHOD THEREOF

(75) Inventor: Hiroyasu JOBETTO, Tokyo (JP)

Correspondence Address: HOLTZ, HOLTZ, GOODMAN & CHICK PC, 220 Fifth Avenue, 16TH Floor, NEW YORK, NY, 10001-7708, US

(73) Assignee: Casio Computer Co., Ltd., Tokyo (JP)

(21) Appl. No.: 12/828,424

(22) Filed: Jul. 1, 2010

(30) Foreign Application Priority Data
Jul. 2, 2009 (JP) 2009-157795

(51) Int. Cl. H01L 23/28; H01L 21/56

(52) U.S. Cl. 257/773; 438/126; 257/E23.116; 257/E21.502

(57) ABSTRACT

Disclosed in a semiconductor device including a semiconductor chip including an electrode, a projection electrode, an sealing film for encapsulating the semiconductor chip and the projection electrode, a first wiring lines provided on one surface of the sealing film, which is electrically connected with the electrode and the projection electrode, a second wiring lines provided on the other surface of the sealing film, which is electrically connected with the projection electrode and at least one of a first via hole conductor for electrically connecting the first wiring lines and the projection electrode or a second via hole conductor for electrically connecting the second wiring lines and the projection electrode, and an area of the projection electrode in an interface where the projection electrode and the first via hole conductor contact each other is greater than an area of the first via hole conductor in the interface and an area of the projection electrode in an interface where the projection electrode and the second via hole conductor contact each other is greater than an area of the second via hole conductor in the interface.

### BACKGROUND OF THE INVENTION

1. Field of the Invention

The present invention relates to a semiconductor device including an sealing film for encapsulating a semiconductor chip and projection electrodes and a manufacturing method thereof.

2. Description of Related Art

JP 2008-42063 discloses a semiconductor device in which an electrode of a semiconductor chip which is mounted on one surface of a substrate and an external electrode which is formed on the other surface of the substrate are made to be electrically connected by forming a via hole on the substrate and by filling conductor in the via hole.

However, because the semiconductor chip is mounted on the substrate, the entire semiconductor device becomes thick due to the thickness of the substrate. Therefore, it is attempted to mount the semiconductor chip on an insulating film. When the semiconductor chip is mounted on a simple body of the insulating film, the insulating film will be deformed. Therefore, the semiconductor chip is mounted on the insulating film in a state where the insulating film is supported by a supporting base material. Then, after mold forming an sealing film on the insulating film, the base plate is to be removed by etching and the like. Thereafter, between-layer connection is carried out by providing conductor in the via hole after forming the via hole which penetrates to the electrode of the semiconductor chip in the insulating film and also by providing plating of the conductor on the wall surface of the through hole after the through hole is formed so as to penetrate the insulating film and the sealing film. Then, a wiring is to be patterned on the surface of the insulating film and the sealing film.

However, when providing plating of conductor on the wall surface of the through hole, there is a problem that great amount of time is needed and that the cost is to be high.

An object of the present invention is to form conductor in the through hole of the semiconductor device promptly and inexpensively.

### SUMMARY OF THE INVENTION

A semiconductor device includes a semiconductor chip having an electrode, a first insulating film in which the first wiring electrically connected with the electrode is provided and in which the semiconductor chip is fixed on one surface thereof, a second insulating film which is disposed so as to face the surface of the first insulating film in which the semiconductor chip is fixed and in which the second wiring is provided, projection electrodes which are provided in the semiconductor chip side which is one of the sides of the facing surface of the first insulating film and the second insulating film and which are formed of a conductor which electrically connects the first wiring and the second wiring and an sealing film which is provided between the first insulating film and the second insulating film and which encapsulates the semiconductor chip and the projection electrodes. Therefore, the conductor in the through holes of the semiconductor device can be formed promptly and in low cost.

According to one aspect of the present invention, there is provided a semiconductor device including a semiconductor chip including an electrode, a projection electrode, an sealing film for encapsulating the semiconductor chip and the projection electrode, a first wiring provided on one surface of the sealing film, which is electrically connected with the electrode and the projection electrode, a second wiring provided on the other surface of the sealing film, which is electrically connected with the projection electrode and at least one of a first via hole conductor for electrically connecting the first wiring and the projection electrode or a second via hole conductor for electrically connecting the second wiring and the projection electrode, and an area of the projection electrode in an interface where the projection electrode and the first via hole conductor contact each other is greater than an area of the first via hole conductor in the interface and an area of the projection electrode in an interface where the projection electrode and the second via hole conductor contact each other is greater than an area of the second via hole conductor in the interface.

According to another aspect of the present invention, there is provided a manufacturing method of a semiconductor device including encapsulating a semiconductor chip including an electrode and a projection electrode by an sealing film, forming a first wiring on one surface of the sealing film, which is electrically connected with the electrode, forming a second wiring on the other surface of the sealing film and electrically connecting the first wiring and the second wiring by the projection electrode.

According to the present invention, degree of freedom of wiring on the surface of the semiconductor device can be improved.

### BRIEF DESCRIPTION OF THE DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1 is a sectional diagram of a semiconductor device 1A according to the first embodiment of the present invention.

FIG. 2 is an explanatory drawing of a manufacturing method of the semiconductor device 1A;

FIG. 3 is an explanatory drawing of the manufacturing method of the semiconductor device 1A;

FIG. 4 is an explanatory drawing of the manufacturing method of the semiconductor device 1A;

FIG. 5 is an explanatory drawing of the manufacturing method of the semiconductor device 1A;

FIG. 6 is an explanatory drawing of the manufacturing method of the semiconductor device 1A;

FIG. 7 is an explanatory drawing of the manufacturing method of the semiconductor device 1A;

FIG. 8 is an explanatory drawing of the manufacturing method of the semiconductor device 1A;

FIG. 9 is an explanatory drawing of the manufacturing method of the semiconductor device 1A;

FIG. 10 is an explanatory drawing of the manufacturing method of the semiconductor device 1A;

FIG. 11 is an explanatory drawing of the manufacturing method of the semiconductor device 1A;

FIG. 12 is an explanatory drawing of the manufacturing method of the semiconductor device 1A;

FIG. 13 is an explanatory drawing of the manufacturing method of the semiconductor device 1A;

FIG. 14 is a sectional diagram of a semiconductor device 1B according to the second embodiment of the present invention.

FIG. 15 is a plan view of an embedded wiring lines 36;

FIG. 16 is an explanatory drawing of the manufacturing method of the semiconductor device 1B;

FIG. 17 is an explanatory drawing of the manufacturing method of the semiconductor device 1B;

FIG. 18 is an explanatory drawing of the manufacturing method of the semiconductor device 1B;

FIG. 19 is an explanatory drawing of the manufacturing method of the semiconductor device 1B.

FIG. 20 is an explanatory drawing of the manufacturing method of the semiconductor device 1B;

FIG. 21 is an explanatory drawing of the manufacturing method of the semiconductor device 1B;

FIG. 22 is an explanatory drawing of the manufacturing method of the semiconductor device 1B;

FIG. 23 is an explanatory drawing of the manufacturing method of the semiconductor device 1B;

FIG. 24 is an explanatory drawing of the manufacturing method of the semiconductor device 1B;

FIG. 25 is an explanatory drawing of the manufacturing method of the semiconductor device 1B;

FIG. 26 is an explanatory drawing of the manufacturing method of the semiconductor device 1B;

FIG. 27 is an explanatory drawing of the manufacturing method of the semiconductor device 1B;

FIG. 28 is an explanatory drawing of the manufacturing method of the semiconductor device 1B;

FIG. 29 is a sectional diagram of a semiconductor device 1C according to the first modification of the present invention.

FIG. 30 is a sectional diagram of a semiconductor device 1D according to the second modification of the present invention;

FIG. 31 is a sectional diagram of a semiconductor device 1E according to the third embodiment of the present invention.

FIG. 32 is an explanatory drawing of a manufacturing method of the semiconductor device 1E;

FIG. 33 is an explanatory drawing of the manufacturing method of the semiconductor device 1E;

FIG. 34 is an explanatory drawing of the manufacturing method of the semiconductor device 1E;

FIG. 35 is an explanatory drawing of the manufacturing method of the semiconductor device 1E;

FIG. 36 is an explanatory drawing of the manufacturing method of the semiconductor device 1E;

FIG. 37 is an explanatory drawing of the manufacturing method of the semiconductor device 1E;

FIG. 38 is an explanatory drawing of the manufacturing method of the semiconductor device 1E;

FIG. 39 is an explanatory drawing of the manufacturing method of the semiconductor device 1E;

FIG. 40 is an explanatory drawing of a manufacturing method of a semiconductor device according to the third modification of the present invention;

FIG. 41 is an explanatory drawing of the manufacturing method of the semiconductor device according to the third modification of the present invention;

FIG. 42 is an explanatory drawing of the manufacturing method of the semiconductor device according to the third modification of the present invention;

FIG. 43 is an explanatory drawing of the manufacturing method of the semiconductor device according to the third modification of the present invention;

FIG. 44 is an explanatory drawing of a manufacturing method of a semiconductor device according to the fourth modification of the present invention;

FIG. 45 is an explanatory drawing of the manufacturing method of the semiconductor device according to the fourth modification of the present invention;

FIG. 46 is an explanatory drawing of the manufacturing method of the semiconductor device according to the fourth modification of the present invention; and

FIGS. 47A, 47B and 47C are sectional diagrams showing semiconductor constituents of other forms.

### DESCRIPTION OF THE PREFERRED EMBODIMENTS

Hereinafter, preferred embodiments for carrying out the present invention will be described with reference to the drawings. Although various limitations which are technically preferable for carrying out the present invention are accompanied to the following embodiments, scope of the invention is not limited to the following embodiments and the examples shown in the drawings.

### First Embodiment

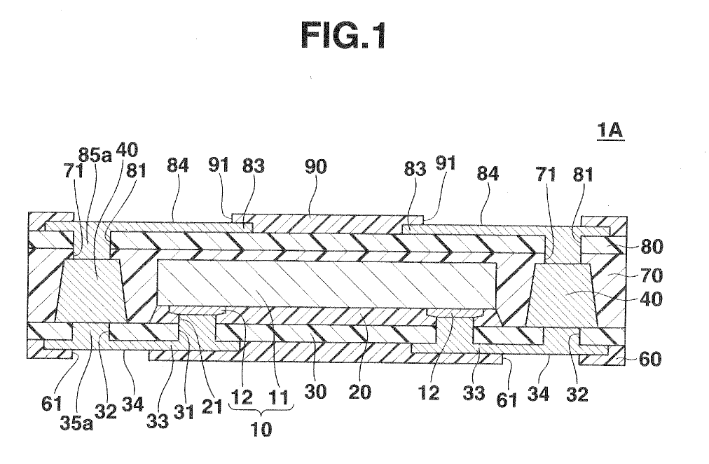

FIG. 1 is a sectional diagram of a semiconductor device 1A according to the first embodiment of the present invention. In the semiconductor device 1A, a semiconductor constituent 10 is packaged. The semiconductor constituent 10 includes a semiconductor chip 11 and a plurality of electrodes 12. The semiconductor chip 11 is formed by providing an integrated circuit on a semiconductor substrate which is a silicon substrate. The plurality of electrodes 12 are provided on an under surface of the semiconductor chip 11. The electrodes 12 are formed of Cu. Here, the electrodes 12 may be a part of a wiring line.

As shown in FIG. 1, the under surface of the semiconductor constituent 10 is adhered to the upper surface of the first insulating film 30 by an adhesive resin layer 20. The adhesive resin layer 20 is formed of a heat-curable resin such as an epoxy resin and has insulating properties. The adhesive resin layer 20 is not fiber-reinforced.

The first insulating film 30 is a fiber-reinforced resin film. In particular, the first insulating film 30 is formed of a composite of a glass fabric board material epoxy resin, a glass fabric board material polyimide resin and other glass fabric board material insulating resins.

In the first insulating film 30 and the adhesive resin layer 20, via holes 31 and 21 are respectively formed as positions corresponding to the electrodes 12. Further, on the upper surface of the first insulating film 30, a plurality of projection electrodes 40 formed of conductor are formed so as to neighbor the semiconductor constituent 10. At the first insulating film 30, via holes 32 are respectively formed at the positions corresponding to the plurality of projection electrodes 40.

At the under surface of the first insulating film 30, lower layer wiring lines (the first wiring lines) 33 are respectively provided integrally with the via hole conductor 35a which is filled in the via holes 21, 31 and 32. The lower layer wiring lines 33 make the electrodes 12 and the projection electrodes 40 so as to electrically communicate with each other.

The lower layer wiring lines 33 is covered with a lower layer overcoat film 60. Portions where overlap the contact pads 34 of the lower layer wiring lines 33 within the lower layer overcoat film 60, openings 61 are respectively formed. A solder bump or the like is formed at the contact pads 34.

On the upper surface of the first insulating film 30, an sealing film 70 for encapsulating the semiconductor constituent 10 and the projection electrodes 40 is provided. The sealing film 70 is formed of an epoxy resin, a polyimide resin and other insulating resins. It is preferred that the sealing film 70 is formed of a heat-curable resin (for example, an epoxy resin) which includes filler. Here, the sealing film 70 is not fiber-reinforced as in a glass fabric board material insulating resin. However, the sealing film 70 may be formed of a fiber-reinforced resin.

On the upper surface of the sealing film 70, the second insulating film 80 is provided. The second insulating film 80 is a fiber-reinforced resin film. In particular, the second insulating film 80 is formed of a composite of a glass fabric board material epoxy resin, a glass fabric board material polyimide resin and other glass fabric board material insulating resins.

In the second insulating film 80 and in the sealing film 70, via holes 81 and 71 are respectively formed at positions corresponding to the plurality of projection electrodes 40.

On the upper surface of the second insulating film 80, upper layer wiring lines 83 are provided integrally with via hole conductors 85a which are filled in the via holes 81 and 71. The upper layer wiring lines 83 electrically communicate with the projection electrodes 40.

In the interfaces where the projection electrode 40 and the via hole conductors 35a and 85a contact with each other, respectively, the area of the projection electrode 40 is greater than the area of each of the via hole conductors 35a and 85a at the interfaces.

The upper layer wiring line 83 is covered with an upper layer overcoat film 90. At portions where overlap the contact pads 84 of the upper layer wiring lines 83 within the upper layer overcoat film 90, openings 91 are respectively formed.

Here, in the openings 61 and 91, the surface of the contacts pads 34 and 84 may be plaited (for example, a simple layer plaiting of gold plating, a two layer plaiting of nickel plating and gold plating or the like).

The lower layer wiring lines 33, the upper layer wiring lines 83 and the projection electrodes 40 are formed of copper, nickel or a laminated body of nickel and copper. Here, the lower layer wiring lines 33, the upper layer wiring lines 83 and the projection electrodes 40 may be formed of other metals.

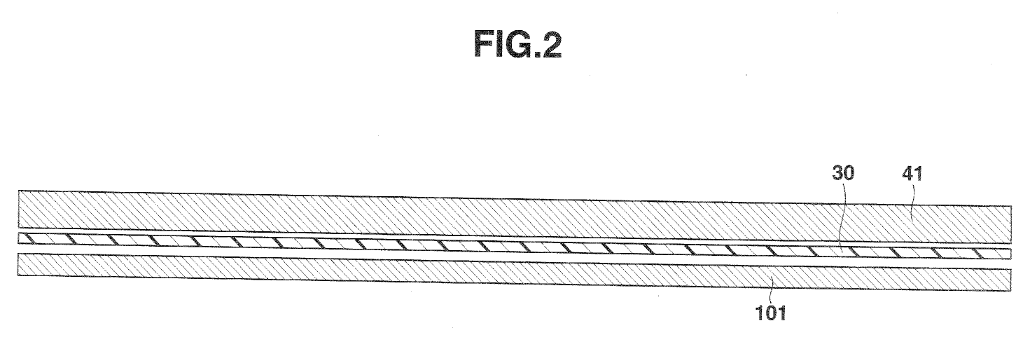

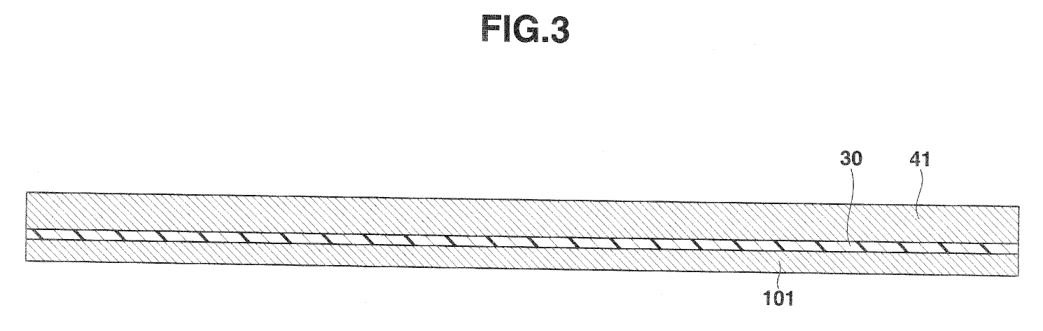

Next, a manufacturing method of the semiconductor device 1A will be described. First, as shown in FIG. 2, the first insulating film 30 and the metal layer 41 are orderly laminated on the first base plate 101 formed of metal, and the laminated body is integrated as shown in FIG. 3 by a hot press molding.

The first base plate 101 is a carrier for making the first insulating film 30 so as to be easy to handle. In particular, the first base plate 101 is a copper foil. The metal layer 41 is formed of the same material as the projection electrodes 40.

The size of the first insulating film 30 and the metal layer 41 which are prepared as described above is a size where a plurality of the semiconductor devices 1A shown in FIG. 1 can be taken out by dicing. Further, the size of the first base plate 101 is larger than the size of the first insulating film 30 and the metal layer 41.

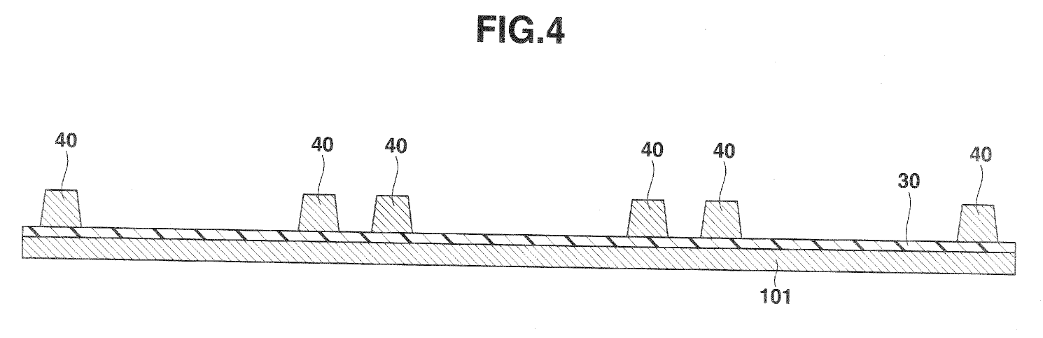

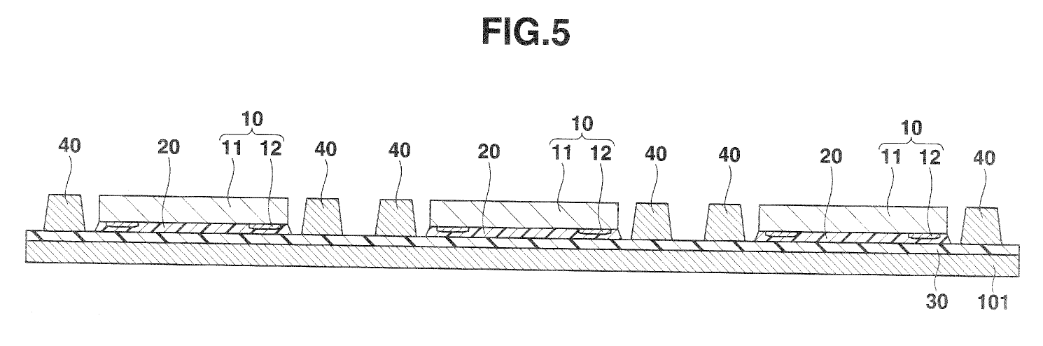

Next, by etching the metal layer 41, the projection electrodes 40 having a shape of circular truncated cone are formed as shown in FIG. 4. Next, as shown in FIG. 5, the adhesive resin layer 20 is applied on the upper surface of the first insulating film 30 at the positions between the projection electrodes 40, and the semiconductor constituents 10 are disposed so as to be face down bonded on the adhesive resin layer 20. In particular, after the non-conductive paste (NCP) is applied by a print method or a dispenser method or after a non-conductive film (NCF) is provided in advance, the semiconductor constituents 10 are lowered in a state where the under surface thereof facing the non-conductive paste or the non-conductive film and the semiconductor constituents 10 are fixed by heat and pressure. The non-conductive paste or the non-conductive film cures and becomes the adhesive resin layer 20.

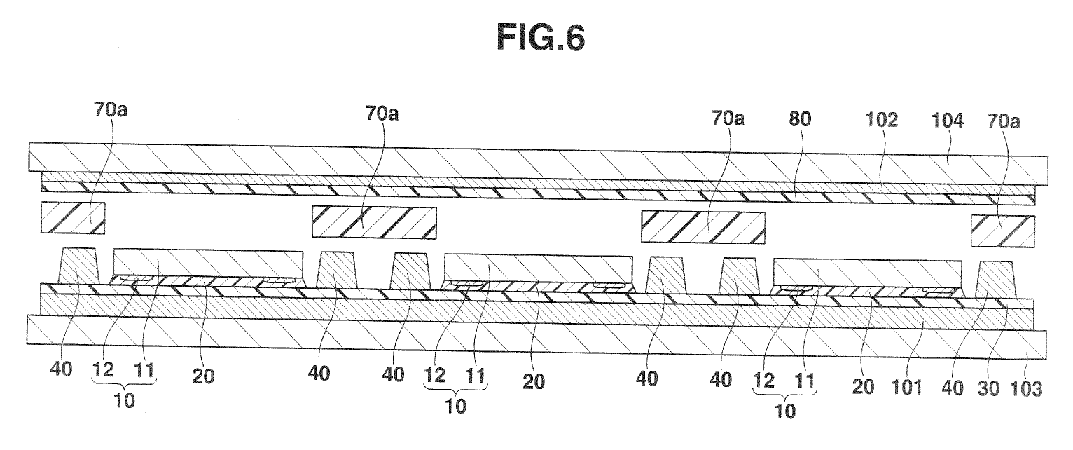

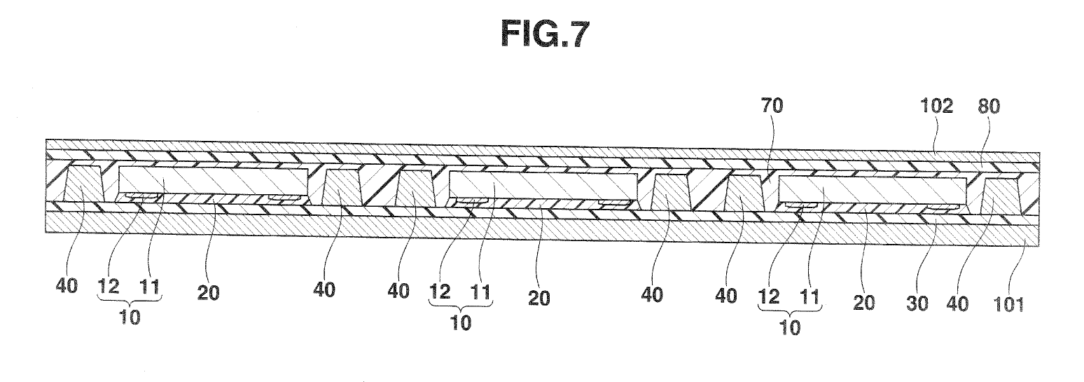

Next, as shown in FIG. 6, preparation is to be carried out by forming the second insulating film 80 on one surface of the second base plate 102 which is formed of metal, and also, the heat-curable resin sheets 70a are prepared. The material for the second base plate 102 is same as the material for the first base plate 101, and the material for the second insulating film 80 is same as the material for the first insulating film 30. The heat-curable resin sheets 70a are formed by including filler in the epoxy resin, the polyimid resin and other heat curable resinz and by making the filler included heat-curable resin be in a half-cured state and formed in a sheet form.

Next, as shown in FIG. 6, the heat-curable resin sheets 70a are placed on the projection electrodes 40 and the second base plate 102 is placed on the heat-curable resin sheets 70a and the semiconductor constituents 10 in a state where the second insulating film 80 side facing downward. Further, this laminated body is sandwiched by a pair of heat platens 103 and 104. Then, the first base plate 101, the first insulating film 30, the heat-curable resin sheets 70a, the second insulating film 80 and the second base plate 102 are hot pressed by the heat platens 103 and 104. By applying heat and pressure, the heat-curable resin sheets 70a are compressed and cured between the second insulating film 80 and the first insulating film 30. Thereby, the sealing film 70 for encapsulating the semiconductor constituent 10 and the adhesive resin layer 20 is formed.

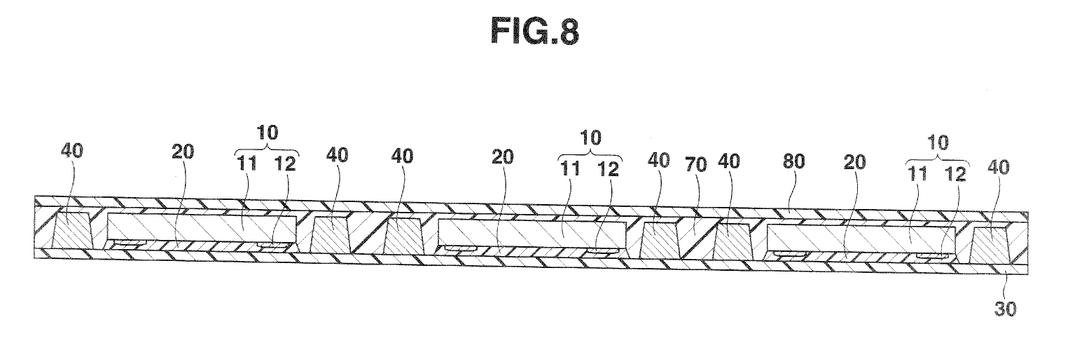

Next, as shown in FIG. 8, the first base plate 101 and the second base plate 102 are removed by etching (for example, by chemical etching or wet etching). Even when the base plates 101 and 102 are removed, sufficient strength can be secured by the laminated structure of the sealing film 70, the second insulating film 80 and the first insulating film 30. Further, the base plates 101 and 102 which are needed during the manufacturing process are removed, therefore, the thickness of the final semiconductor device 1A can be made to be thin.

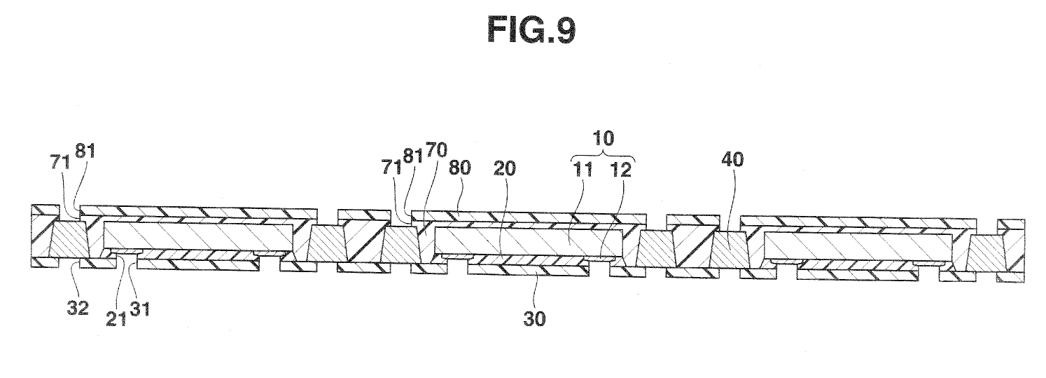

Next, laser beam is irradiated to the positions correspond to the electrodes 12 and the projection electrodes 40 from the first insulating film 30 side until the electrodes 12 and the projection electrodes 40 are exposed. Thereby, as shown in FIG. 9, the via holes 21, 31 and 32 are respectively formed in the first insulating film 30 and the adhesive resin layer 20. Further, laser beam is irradiated to the positions corresponding to the projection electrodes 40 from the second insulating film 80 side to form the via holes 81 and 71, respectively, in the second insulating film 80 and the sealing film 70.

As for the laser, it is preferred to use the carbon dioxide gas laser (CO₂ laser). This is because the lower layer insulating film 30 is formed of a fiber-reinforced resin. Here, after forming the via holes 31, 32 and 81, the via holes 21 and 71 may be formed by the ultraviolet laser (UV laser) or the low poser CO laser.

Next, inside of the via holes 21, 31, 32, 71 and 81 are desmeared.

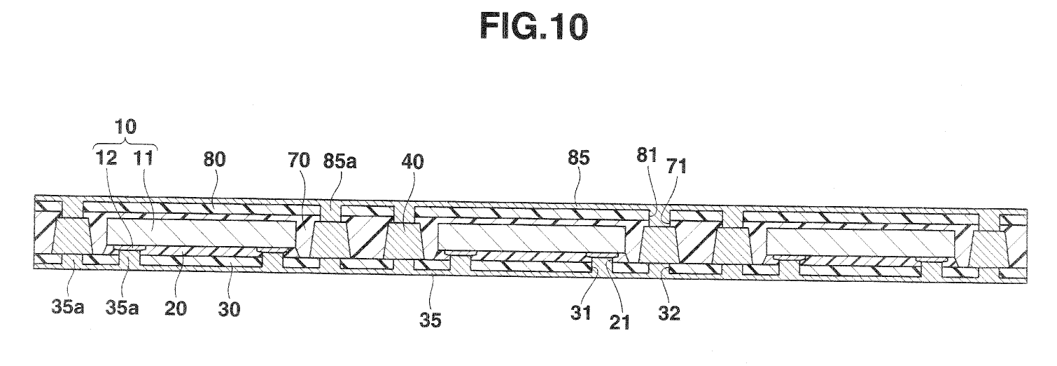

Next, as shown in FIG. 10, by carrying out electroless plaiting and electroplating in order, the metal plate films 35 and 85 are formed on the entire surface of the second insulating film 80 and the first insulating film 30. At this time, the via holes 21, 31 and 32 are filled with a portion (the via hole conductor 35a) of the metal plate film 35, and also, the via holes 71 and 81 are filled with a portion (the via hole conductor 85a) of the metal plate film 85.

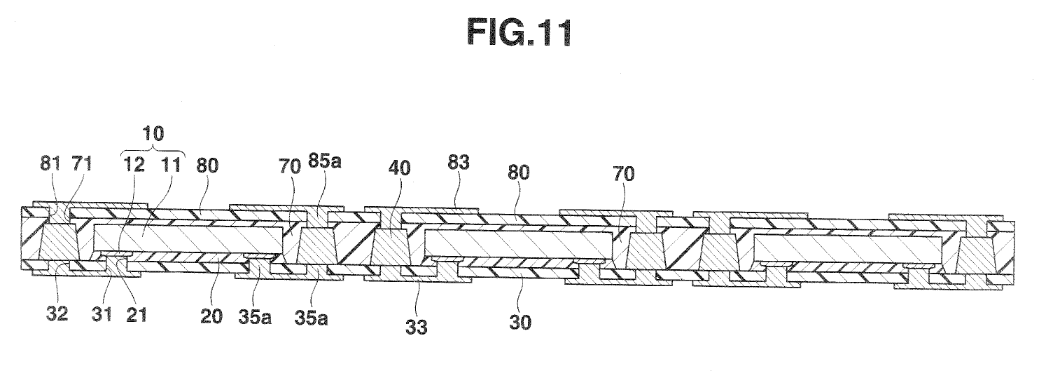

Next, as shown in FIG. 11, by patterning the metal plate films 35 and 85 by the photolithographic method or the etching method, the metal plate film 35 is processed to be the lower layer wiring lines 33 and the metal plate film 85 is processed to be the second wiring lines 83. Here, the patterning of the lower layer wiring lines 33 and the second wiring lines 83 may be carried out by the semi-additive method or the full-additive method instead of carrying out the patterning of the lower layer wiring lines 33 and the second wiring lines 83 by the above described subtractive method.

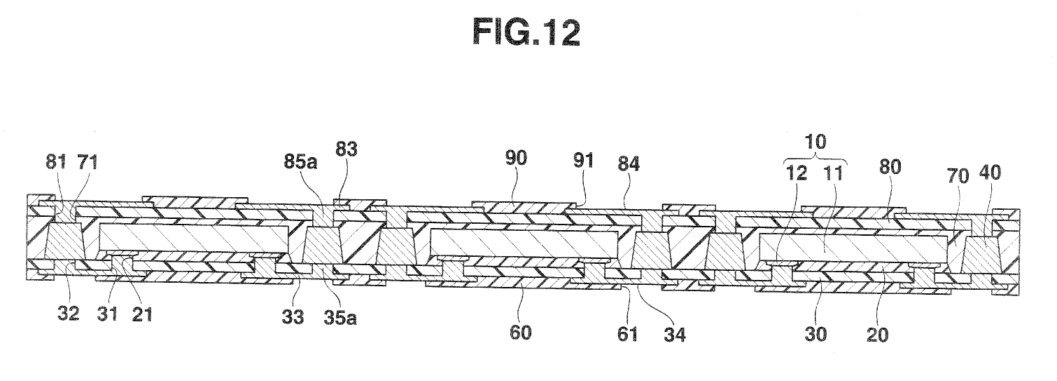

Next, as shown in FIG. 12, by printing a resin material on the surface of the first insulating film 30 and on the lower layer wiring lines 33 and by curing the resin material, the lower layer overcoat film 60 is patterned. In a similar way, the upper layer overcoat film 90 is patterned on the surface of the second insulating film 80 and on the second wiring lines 83. By the patterning of the lower layer overcoat film 60 and the upper layer overcoat film 90, the openings 61 and 91 are formed and the pads 34 and 84 are exposed in the openings 61 and 91.

Here, the lower layer overcoat film 60 and the upper layer overcoat film 90 may be patterned by applying a photosensitive resin to the entire surface of the first insulating film 30, the lower layer wiring line 33, the second insulating film 80 and the second wiring lines 83 by the dip-coat method or the spin-coat method and by being exposed to light and developed.

Next, the terminal process for forming a gold plate or a nickel plate/gold plate on the surface of the pads 34 and 84 in the openings 61 and 91 by the electroless plaiting is carried out.

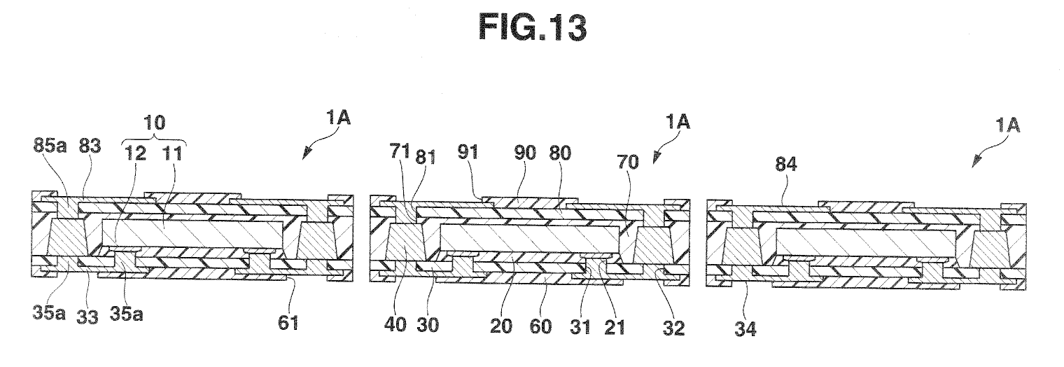

Next, as shown in FIG. 13, a plurality of semiconductor devices 1A are cut out by the dicing process. Here, a solder bump may be formed in the openings 61 and 91.

According to the semiconductor device 1A manufactured in the above described way, the via holes 21, 31, 32, 71 and 81 can be formed at arbitrary positions within the range of the electrodes 12 and the projection electrodes 40. Therefore, there is a great flexibility in the forming positions of the via holes 21, 31, 32, 71 and 81. Further, lands are very minute. Therefore, there is a great flexibility in the lower layer wiring lines 33 and the second wiring lines 83. Furthermore, the intermediate layer cannot be made to be thinner than the thickness of the IVH substrate when the IVH substrate is used instead of the projection electrodes 40. However, when the projection electrodes 40 are used, the intermediate layer can be made to be thin by lowering the projection electrodes 40.

### Second Embodiment

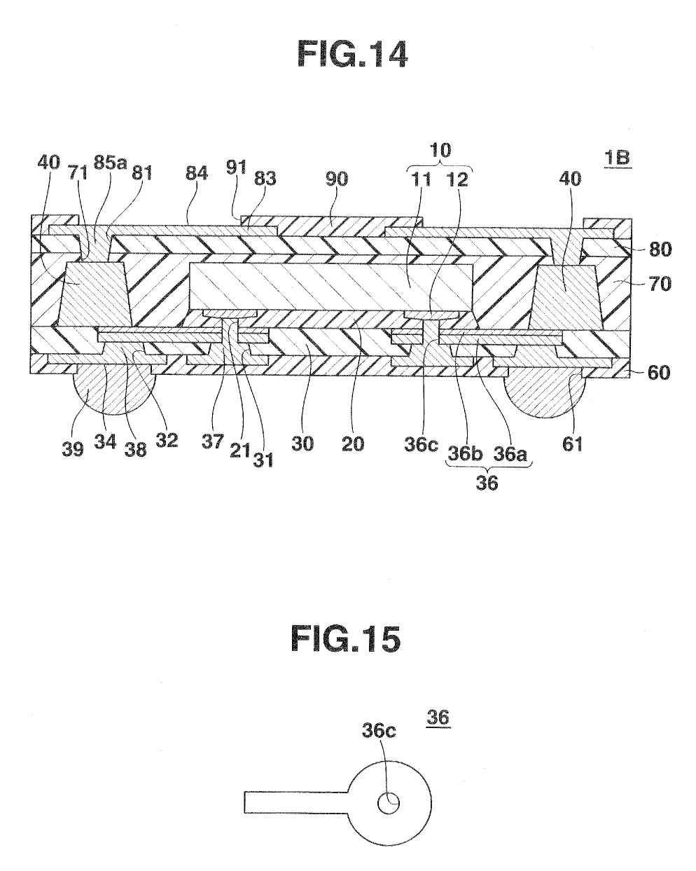

FIG. 14 is a sectional diagram of the semiconductor device 1B according to the second embodiment of the present invention. Here, the same symbols are attached to the structures similar to that of the first embodiment, and the descriptions are omitted.

In the embodiment, the filling materials 37 formed of the conductor filled in the via holes 21 and 31 and the filling materials 38 formed of the conductor filled in the via hole 32 are separated. Further, embedded wiring lines (the first wiring lines) 36 are provided on the upper surface of the first insulating film 30. The embedded wiring lines 36 are formed of the wiring layer 36a and the etching barrier layer 36b, and one end of the embedded wiring lines 36 is provided are the position corresponding to the electrode 12 and the other end is provided at the position corresponding to the projection electrode 40.

FIG. 15 is a plan diagram of the embedded wiring lines 36. As shown in FIG. 15, a through hole 36c is formed in the embedded wiring lines 36 at the portion where the via hole 21 is formed. The filling material 37 and the filling material 38 electrically communicate with each other by the embedded wiring lines 36.

On the under surface of the first insulating film 30, the contact pads 34 which are formed integrally with the filling materials 38 are provided and the solder bump 39 is formed at the contact pads 34.

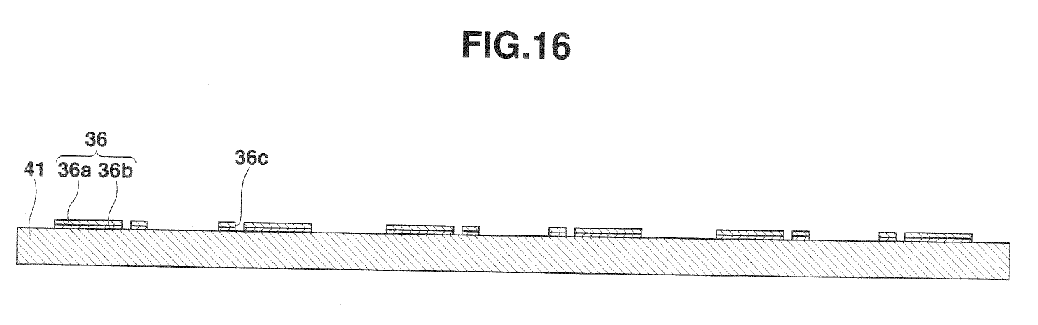

Next, a manufacturing method of the semiconductor device 1B will be described. First, the embedded wiring lines 36 are formed as shown in FIG. 16 by orderly laminating metal layers which become the etching barrier layer 36b and the wiring layer 36a on the metal layer 41 and patterning. The metal layer 41 is formed of the metal same as the metal which forms the wiring layer 36a.

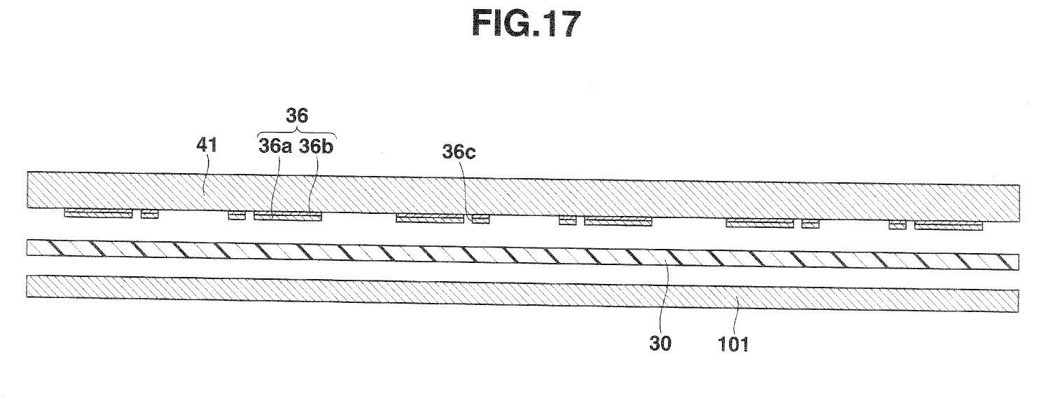

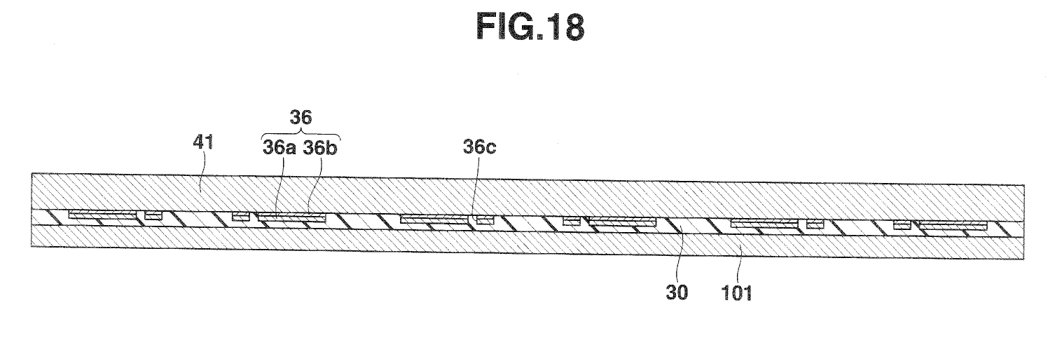

Next, as shown in FIG. 17, the first insulating film 30 is laminated on the first base plate 101, and also, the metal layer 41 is laminate so that the side in which the embedded wiring lines 36 are formed face the first insulating film 30 side. Thereafter, the laminated body is integrated as shown in FIG. 18 by the ho press molding and the embedded wiring lines 36 are embedded in the first insulating film 30.

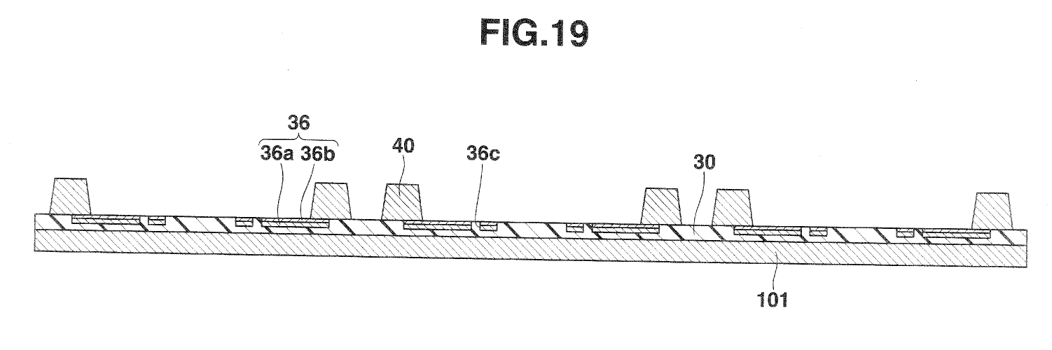

Next, by etching the metal layer 41, the projection electrodes 40 are formed as shown in FIG. 19. At this time, the wiring layers 36a remain because the etching barrier layers 36b exit.

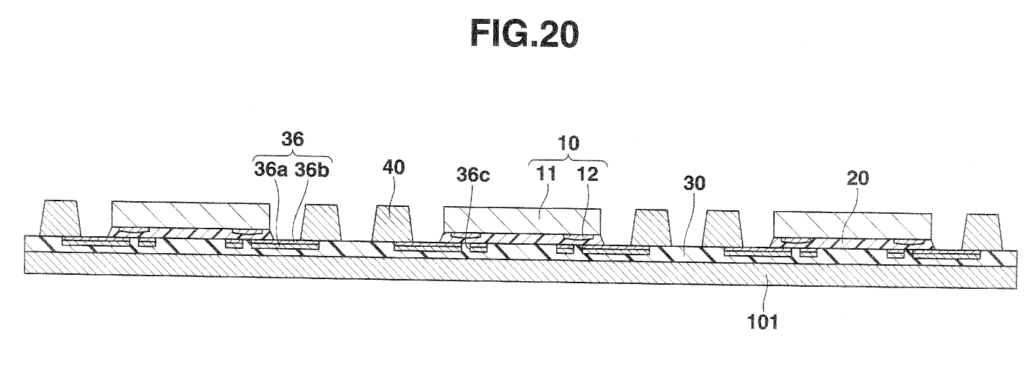

Next, as shown in FIG. 20, the adhesive resin layer 20 is applied to the portions in which the through holes 36c of the embedded wiring lines 36 are formed and the semiconductor constituents 10 are disposed by face down bonding on the adhesive resin layer 20 so that the electrodes 12 are to be disposed above the through holes 36c.

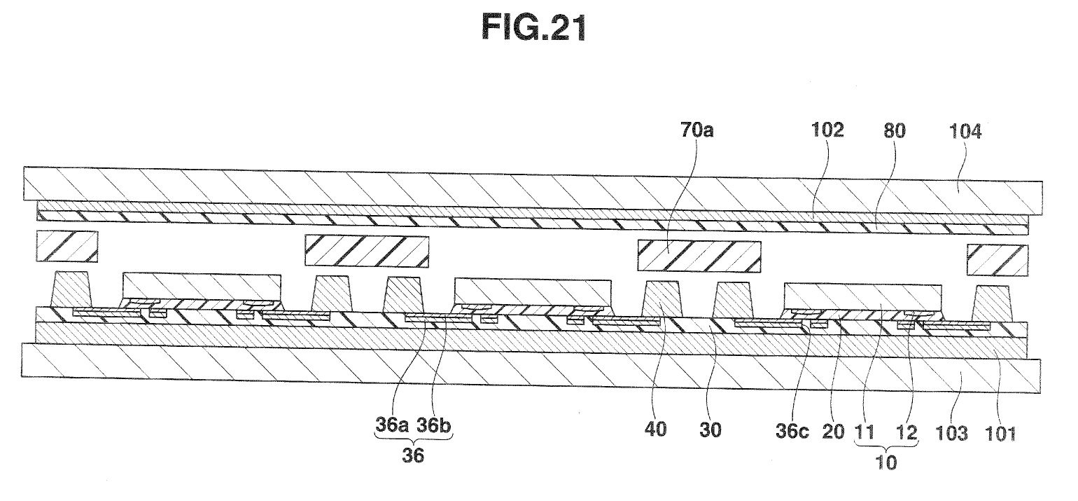

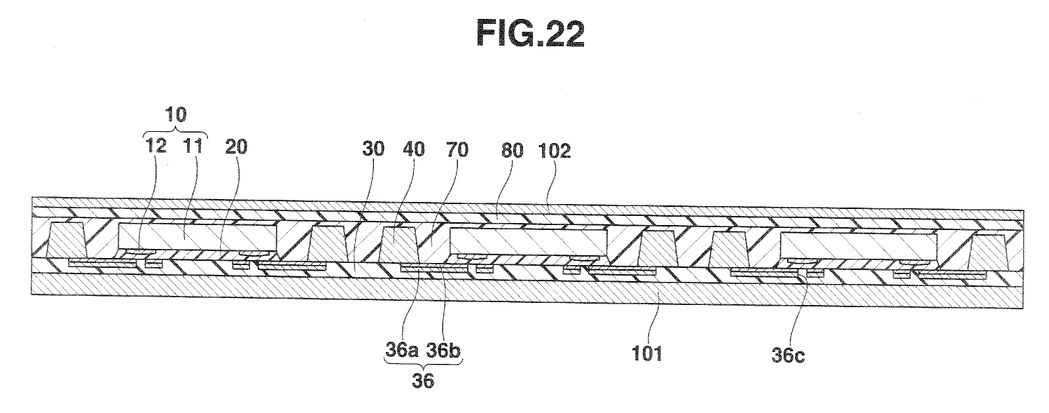

Next, a preparation is carried out by forming the second insulating film 80 on one surface of the second base plate 102 which is formed of metal, and also, the heat-curable resin sheets 70a are prepared. Then, as shown in FIG. 21, the heat-curable resin sheets 70a are placed on the projection electrodes 40 and the second based plate 102 is placed on the heat-curable resin sheets 70a and the semiconductor constituents 10 in a state where the second insulating film 80 side facing downward. Further, this laminated body is sandwiched between a pair of heat platens 103 and 104. Then, the first base plate 101, the first insulating film 30, the heat-curable resin sheets 70a, the second insulating film 80 and the second based plate 102 are hot pressed by the heat platens 103 and 104. By applying heat and pressure, the heat-curable resin sheets 70a are compressed and cured between the second insulating film 80 and the first insulating film 30. Thereby, the sealing film 70 for encapsulating the semiconductor constituents 10 and the adhesive resin layer 20 is formed as shown in FIG. 22.

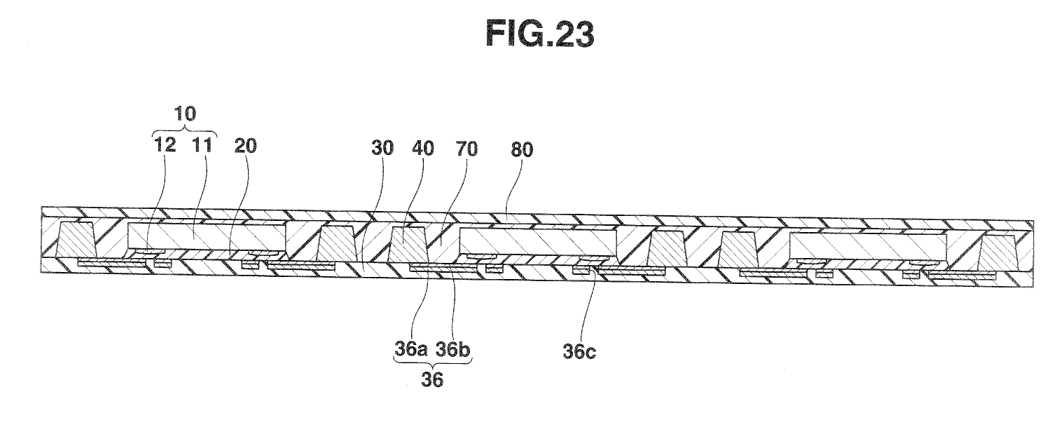

Next, as shown in FIG. 23, the first base plate 101 and the second base plate 102 are removed by etching (for example, by chemical etching or wet etching). Even when the base plates 101 and 102 are removed, sufficient strength can be assured by the laminated structure of the sealing film 70, the second insulating film 80 and the first insulating film 30. Further, the base plates 101 and 102 which are needed during the manufacturing process are removed, therefore, the thickness of the final semiconductor device 1B can be made to be thin.

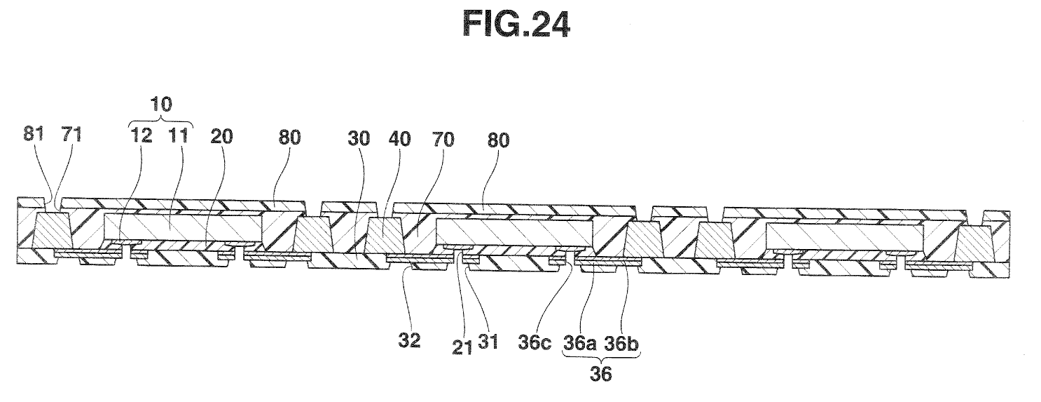

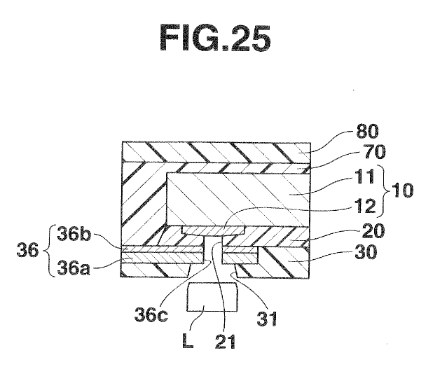

Next, by irradiating laser beam to both end portions of the embedded wiring 36 from the first insulation film 30 side until the electrodes 12 and the embedded wiring lines 36 are exposed, the via holes 21, 31 and 32 are formed in the first insulating film 30 and the adhesive resin layer 20 as shown in FIG. 24. At this time, as shown in FIG. 25, the via hole 21 is formed only at the portion where the laser beam L passes the through hole 36c by the embedded wiring lines 36 acting as a mask.

Similarly, the via holes 81 and 71 are formed in the second insulating film 80 and the sealing film 70 by irradiating laser beam to the positions corresponding to the projection electrodes 40 from the second insulating film 80 side.

Next, inside of the via holes 21, 31, 32, 71 and 81 are desmeared.

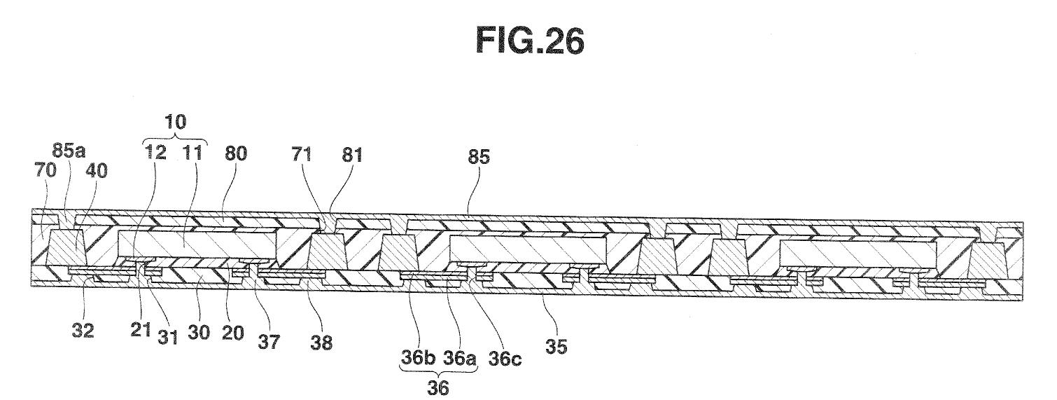

Next, as shown in FIG. 26, by carrying out the electroless plating and the electroplating in order, the metal plate films 35 and 85 are formed on the entire surface of the second insulating film 80 and the first insulating film 30. At this time, the via holes 21, 31 and 32 are filled with a portion (the filling materials 37 and 38) of the metal plate film 35 and the via holes 71 and 81 are filled with a portion (the via hole conductor 85a) of the metal plate film 85.

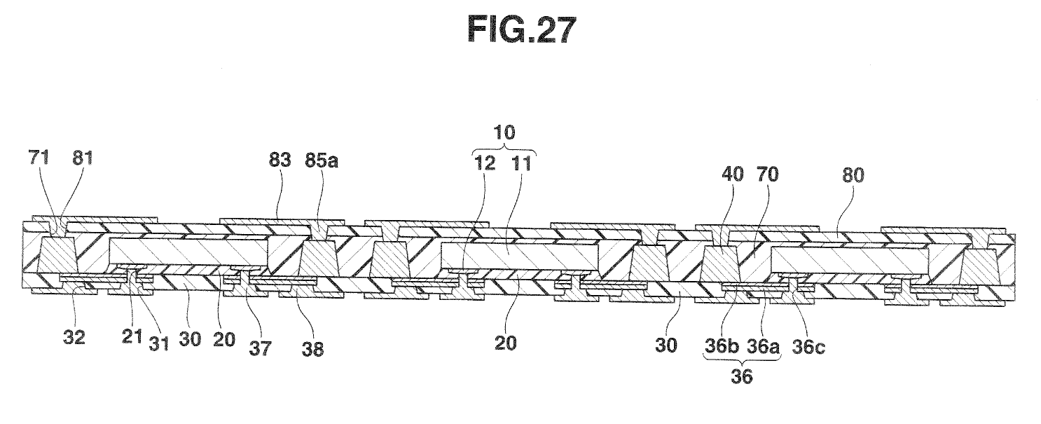

Next, by patterning the metal plate films 35 and 85 by the photolithographic method and the etching method, the metal plate film 35 is processed to be the filling materials 37 and 38 and the metal plate film 85 is processed to be the second wiring lines 83 as shown in FIG. 27. Here, the patterning of the filling materials 37 and 38 and the second wiring lines 83 can be carried out by the semi-additive method or the full-additive method instead of carrying out the patterning of the filling materials 37 and 38 and the second wiring lines 83 by the subtractive method as described above.

Thereafter, by printing a resin material on the surface of the first insulating film 30 and on the filling materials 37 and 38 and by curing the resin material, the lower layer overcoat film 60 is patterned. Similarly, the upper layer overcoat film 90 is patterned on the surface of the second insulating film 80 and on the second wiring lines 83. By the patterning of the lower layer overcoat film 60 and the upper layer overcoat film 90, the openings 61 and 91 are formed and the contact pads 34 and 84 are exposed in the openings 61 and 91.

Here, the lower layer overcoat film 60 and the upper layer overcoat film 90 may be patterned by applying a photosensitive resin on the entire surface of the first insulating film 30, the filling materials 37 and 38, the second insulating film 80 and the second wiring lines 83 by the dip-coat method or the spin-coat method and by exposing line and developing.

Next, the terminal process for forming a gold plate or a nickel plate/gold plate on the surfaces of the pads 34 and 84 in the openings 61 and 91 by the electroless plating is carried out.

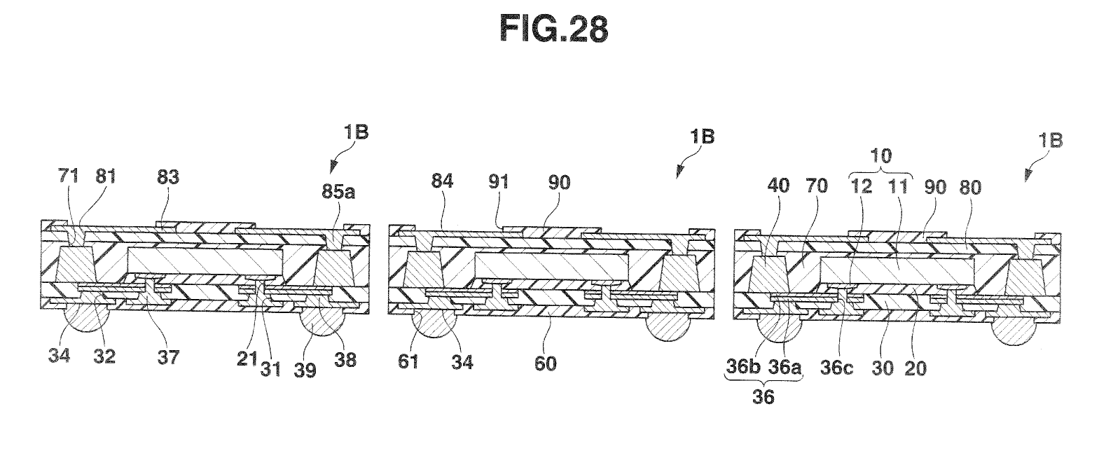

Next, as shown in FIG. 28, a plurality of semiconductor devices 1B are cut out by the dicing process. Here, a solder bump may be formed in the openings 61 and 91.

In the embodiment, lands are also very minute. Therefore, there is a great flexibility in the second wiring lines 83. Further, the through hole 36c of the embedded wiring lines 36 act as a mask at the time of forming the via hole 21. Therefore, the via holes 21 can be formed accurately.

### <Modification 1>

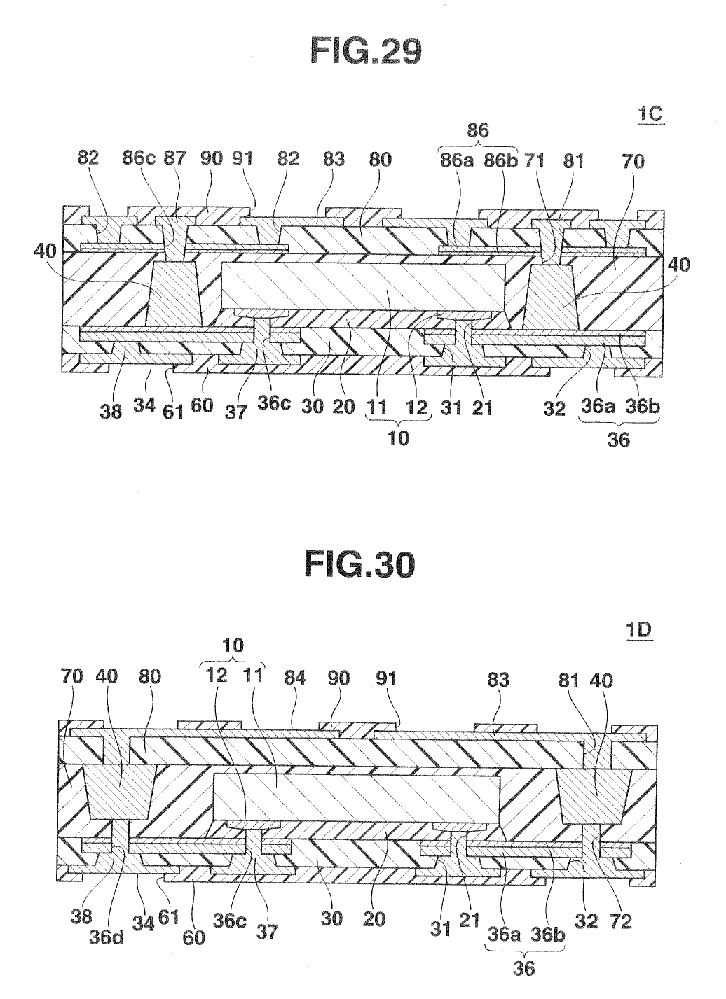

Here, as shown in FIG. 29, the semiconductor device 1C may be structured so that the embedded wiring lines (the second wiring lines) 86 are also provided at the lower surface of the second insulating film 80, that the projection electrodes 40 and the embedded wiring lines 86 are electrically connected by the filling material 87 formed of the conductor which is filled in the via holes 71 and 81 and that the second wiring lines 83 is provided integrally with the conductor which is filled in the via holes 82 which are provided in the second insulating film 80.

The embedded wiring lines 86 are formed of the wiring layer 86a and the etching barrier layer 86b. The method of forming the embedded wiring lines 86 in the second insulating film 80 is similar to the method of forming the embedded wiring lines 36 in the under surface of the first insulating film 30. The via holes 71 are formed by the through holes 86c of the embedded wiring lines 86 acting as a mask.

### <Modification 2>

Alternatively, as shown in FIG. 30, the projection electrodes 40 may be provided on the under surface of the second insulating film 80, and also, the through holes 36d may be provided at the same position as the via holes 32 of the embedded wiring lines 36. Further, the via holes 72 may be formed in the sealing film 70 by the through holes 36d of the embedded wiring lines 36 acting as a mask and the filling material 38 may be filled in the via holes 72. By the through holes 36d acting as a mask, the via holes 72 can be formed accurately.

### Third Embodiment

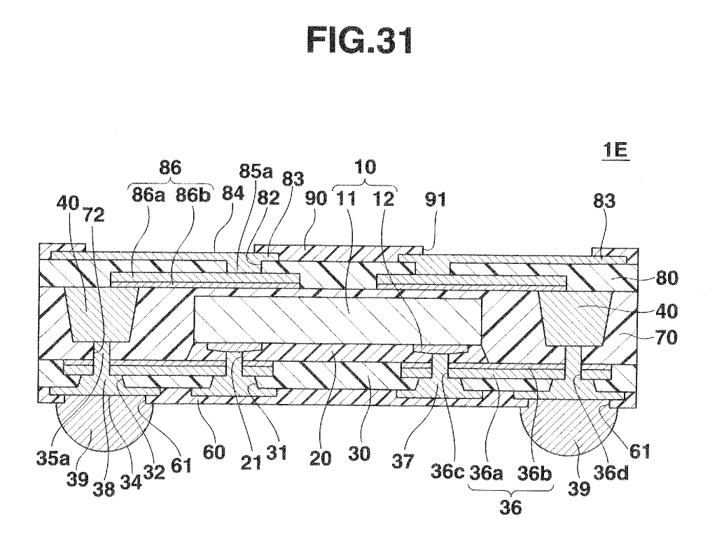

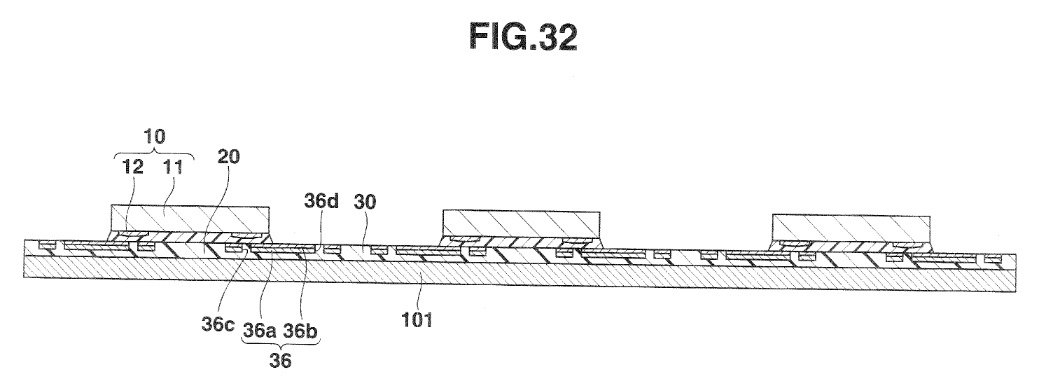

FIG. 31 is a sectional diagram of the semiconductor device 1E according to the third embodiment of the present invention. Here, the same symbols are attached to the structures similar to that of the second embodiment and the descriptions are omitted.

In the embodiment, the projection electrodes 40 are provided on the under surface of the second insulating film 80. Further, one end of the embedded wiring lines 36 are extended to the lower portion of the projection electrodes 40, respectively, and the through holes 36d are provided at the upper portion of the via holes 32 which are the lower portion of the projection electrodes 40.

In the sealing film 70, the via holes 72 are provided at the lower portion of the projection electrodes 40 which is the upper portion of the through holes 36d. The filling material 38 is filled in the via holes 72, 32 and in the through holes 36d.

In the under surface of the second insulating film 80, the embedded wiring lines 86 are provided. The embedded wiring lines 86 are formed of the wiring layer 86a and the etching barrier layer 86b, and one end of the embedded wiring lines 86 are provided at the positions corresponding to the projection electrodes 40, respectively, and the other end of the embedded wiring lines 86 are provided at the upper portion of the semiconductor constituent 10, respectively. The method of forming the embedded wiring lines 86 in the under surface of the second insulating film 80 is similar to the method of forming the embedded wiring lines 36 in the under surface of the first insulating film 30.

In the second insulating film 80, the via holes 82 which penetrate from the upper surface to the end portion of the embedded wiring lines 86 of the semiconductor constituent 10 side are provided. In the upper surface of the second insulating film 80, the second wiring lines 83 are provided integrally with the via hole conductors 85a which are filled in the via holes 82.

Next, a manufacturing method of the semiconductor device 1E will be described. First, similar to the second embodiment, the adhesive resin layer 20 is applied to the portions where the through holes 36c of the embedded wiring lines 36 are formed with respect to the laminated, body of the first base plate 101 and the first insulating film 30 in which the embedded wiring lines 36 are formed, and the semiconductor constituents 10 are disposed on the adhesive resin layer 20 by face down bonding so that the electrodes 12 are to be disposed above the through holes 36c.

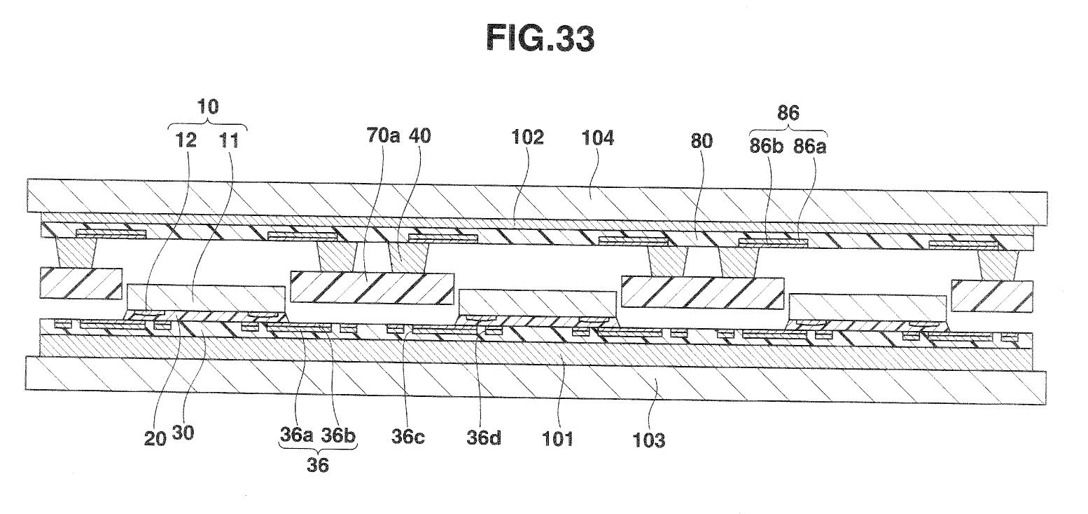

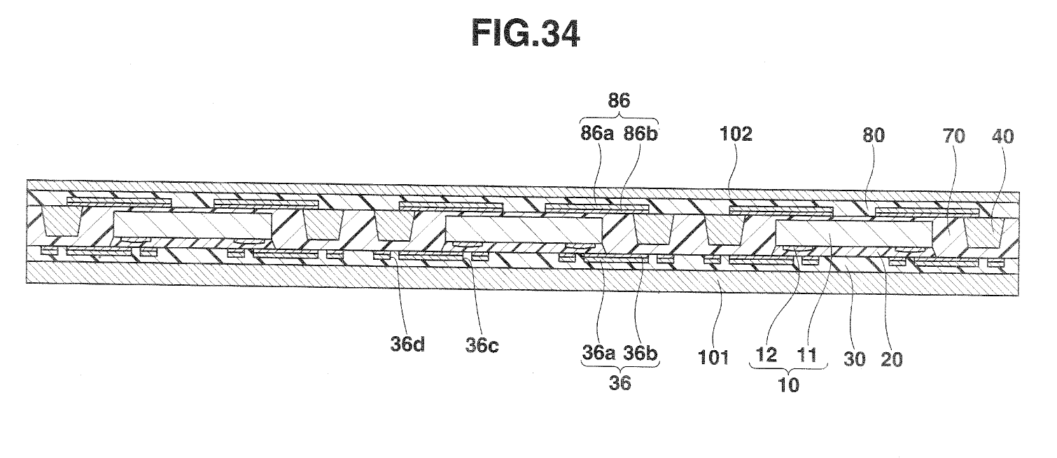

Next, a laminated body of the second base plate 102 and the second insulating film 80 in which the embedded wiring lines 86 and the projection electrodes 40 are formed is prepared, and also, the heat-curing resin sheets 70a are prepared. Then, as shown in FIG. 33, the heat-curable resin sheets 70a are placed between the semiconductor constituents 10 and the second base plate 102 is place so that the projection electrodes 40 are to be disposed on the heat-curing resin sheets 70a in a state where the second insulating film 80 side facing downward. Further, this laminated body is sandwiched by a pair of the heat platens 103 and 104. Then, the first base plate 101, the first insulating film 30, the heat-curable resin sheets 70a, the second insulating film 80 and the second base plate 102 are hot pressed by the heat platens 103 and 104. By applying heat and pressure, the heat-curable resin sheets 70a are compressed and cured between the second insulating film 80 and the first insulating film 30. Thereby, the sealing film 70 for encapsulating the semiconductor constituents 10 and the adhesive resin layer 20 is formed as shown in FIG. 34.

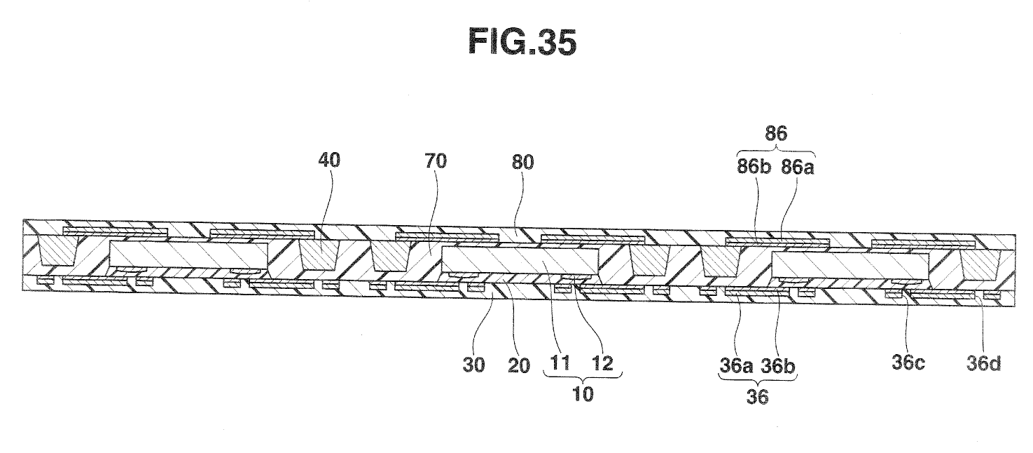

Next, as shown in FIG. 35, the first base plate 101 and the second base plate 102 are removed by etching (for example, by chemical etching or wet etching). Even when the base plates 101 and 102 are removed, sufficient strength can be secured by the laminated structure of the sealing film 70, the second insulating film 80 and the first insulating film 30. Further, the base plates 101 and 102 which are needed during the manufacturing process are removed, therefore, the thickness of the final semiconductor device 1E can be made to be thin.

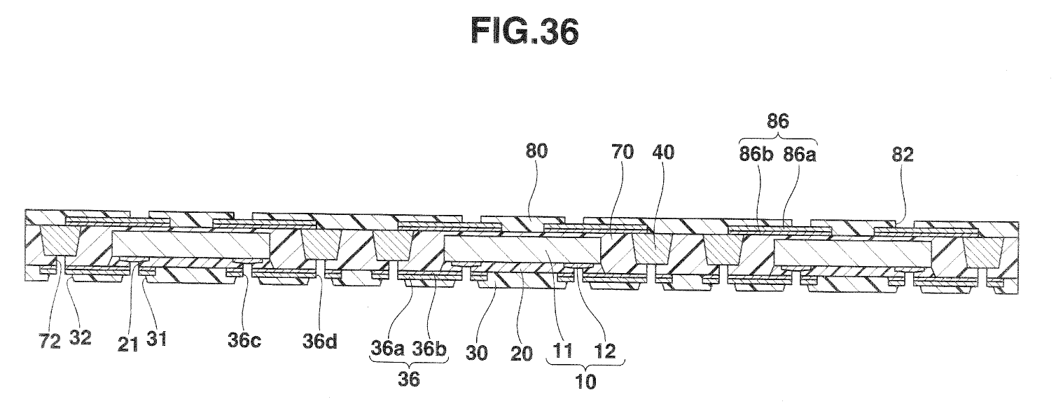

Next, by irradiating laser beam to both end portions of the embedded wiring lines 36 from the first insulating film 30 side until the electrodes 12, the projection electrodes 40 and the embedded wiring lines 36 are exposed, the via holes 21, 31, 32 and 72 are formed in the first insulating film 30, the adhesive resin layer 20 and the sealing film 70 as shown in FIG. 36. At this time, the through holes 36c are used as a mask when forming the via holes 21, and the through holes 36d are used as a mask when forming the via holes 72.

Similarly, the via holes 82 are formed in the second insulating film 80 by irradiating laser beam to the position corresponding to the end portion of the embedded wiring lines 86 from the second insulating film 80 side.

Next, inside of the via holes 21, 31, 32, 72 and 82 are desmeared.

Next, by carrying out the electroless plating and the electroplating in order, the metal plate films 35 and 38 are formed on the entire surface of the second insulating film 80 and the first insulating film 30. At this time, the via holes 21, 31, 32 and 72 are filled with a portion (the filling materials 37 and 38) of the metal plate film 35, and the via holes 82 are filled with a portion (the via hole conductor 85a) of the metal plate film 85.

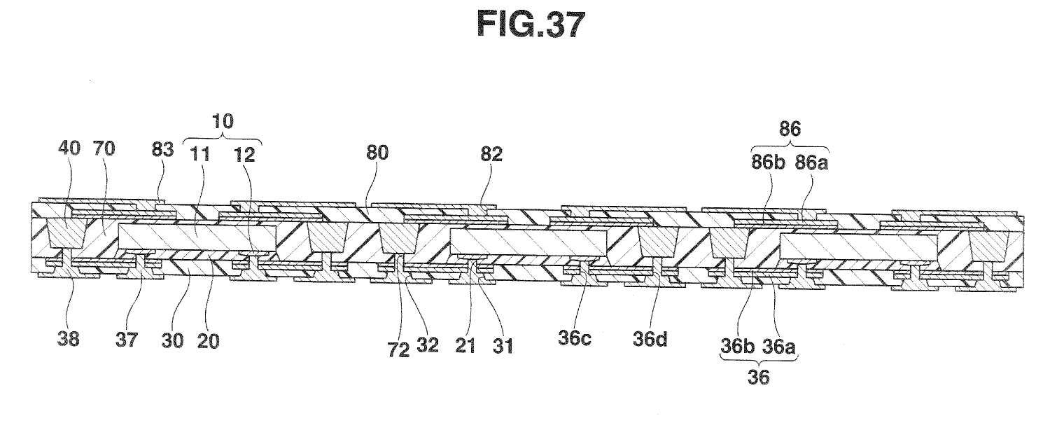

Next, as shown in FIG. 37, by patterning the metal plate films 35 and 85 by the photolithographic method and the etching method, the metal plate film 35 is processed to be the filling materials 37 and 38 and the metal plate film 85 is processed to be the second wiring lines 83. Here, the patterning of the filling materials 37 and 38 and the second wiring lines 83 may be carried out by the semi-additive method or the full-additive method instead of carrying out the patterning of the filling materials 37 and 38 and the second wiring lines 83 by the subtractive method as described above.

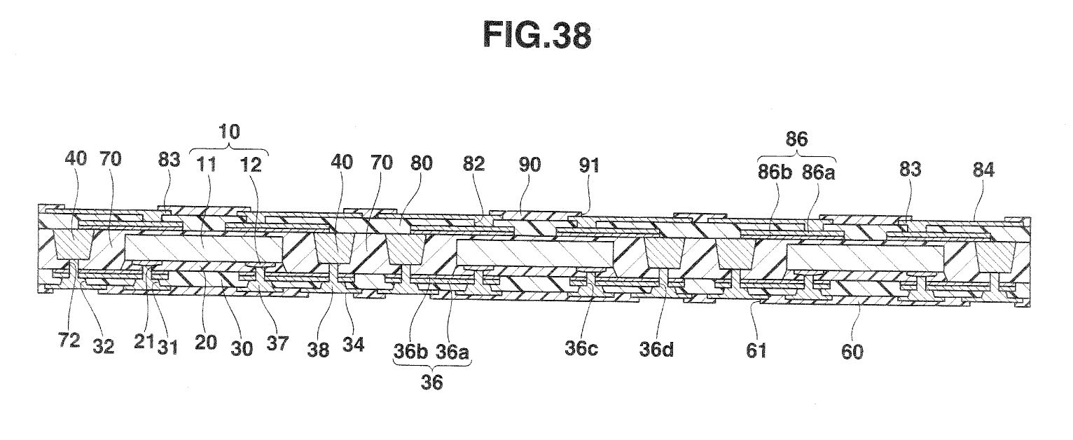

Thereafter, as shown in FIG. 38, by printing a resin material on the surface of the first insulating film 30 and on the filling materials 37 and 38 and by curing the resin material, the lower layer overcoat film 60 is patterned. Similarly, the upper layer overcoat film 90 is patterned on the surface of the second insulating film 80 and on the second wiring lines 83. By the patterning of the lower layer overcoat film 60 and the upper layer overcoat film 90, the openings 61 and 91 are formed and the pads 34 and 84 are exposed in the openings 61 and 91.

Here, the lower layer overcoat film 60 and the upper layer overcoat film 90 may be patterned by applying a photosensitive resin to the entire surface of the first insulating film 30, the lower layer wiring lines 33, the second insulating film 80 and the second wiring lines 83 by the dip-coat method or the spin-coat method and by exposing light and developing.

Next, the terminal process for forming a gold plate or a nickel plate/gold plate on the surface of the pads 34 and 84 in the openings 61 and 91 by the electroless deposition is carried out.

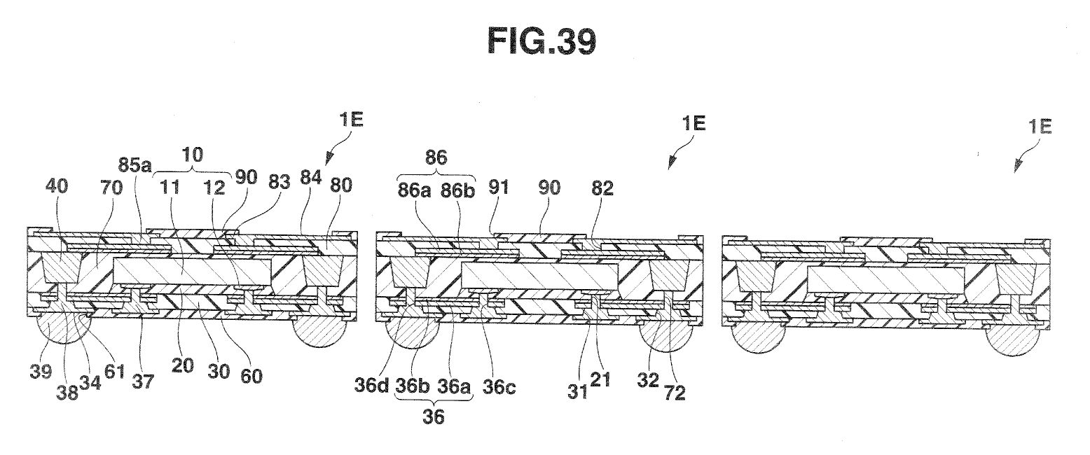

Next, as shown in FIG. 39, a plurality of semiconductor devices 1E are cut out by the dicing process. Here, a solder bump may be formed in the openings 61 and 91.

In the embodiment, lands are also very minute. Therefore, there is a great flexibility in the second wiring lines 83. Further, the through holes 36c and 36d of the embedded wiring lines 36 act as a mask when forming the via holes 21 and 72, respectively. Therefore, the via holes 21 and 72 can be formed accurately.

### <Modification 3>

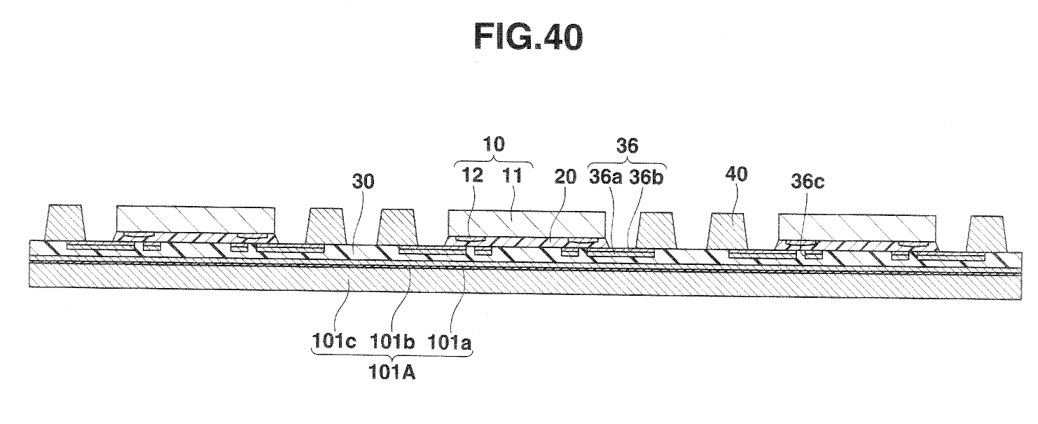

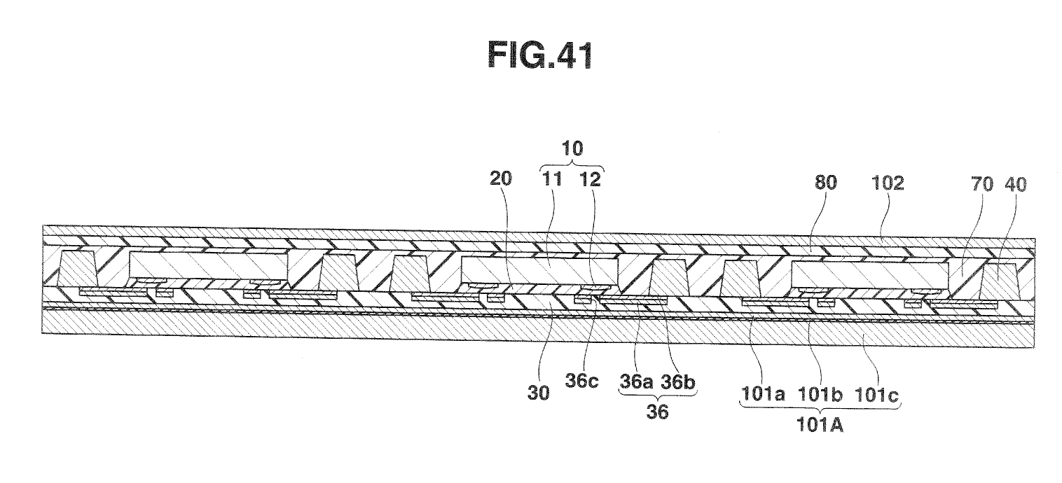

In the above described embodiment, the first base material 101A formed of a pealable copper foil plate may be used. The pealable copper foil plate is formed by forming a release layer 101b on the upper surface of the carrier metal plate 101c formed of a copper plate, a thick copper foil or the like and by forming the copper foil 101a on the upper surface of the release layer 101b by the electroplating as shown in FIG. 40.

In a case where the first base material 101A formed of the pealable copper foil plate is used, the first insulating film 30 is formed on the surface in which the copper foil 101a is formed, the adhesive resin layer 20 is applied on the first insulating film 30 and the semiconductor constituents 10 are disposed on the adhesive resin layer 20 by face down bonding so that the electrodes 12 are disposed above the through holes 36c.

Next, a preparation is carried out by forming the second insulating film 80 on one surface of the second base plate 102 which is formed of metal, and also, the heat-curable resin sheets 70a as shown in FIG. 6 are prepared. Then, the heat-curable resin sheets 70a are placed on the projection electrodes 40 and the second base plate 102 is placed on the heat-curable resin sheets 70a and the semiconductor constituents 10 in a state where the second insulating film 80 side facing downward. Further, by hot pressing this laminated body, the sealing film 70 for encapsulating the semiconductor constituents 10 and the adhesive resin layer 20 is formed as shown in FIG. 40.

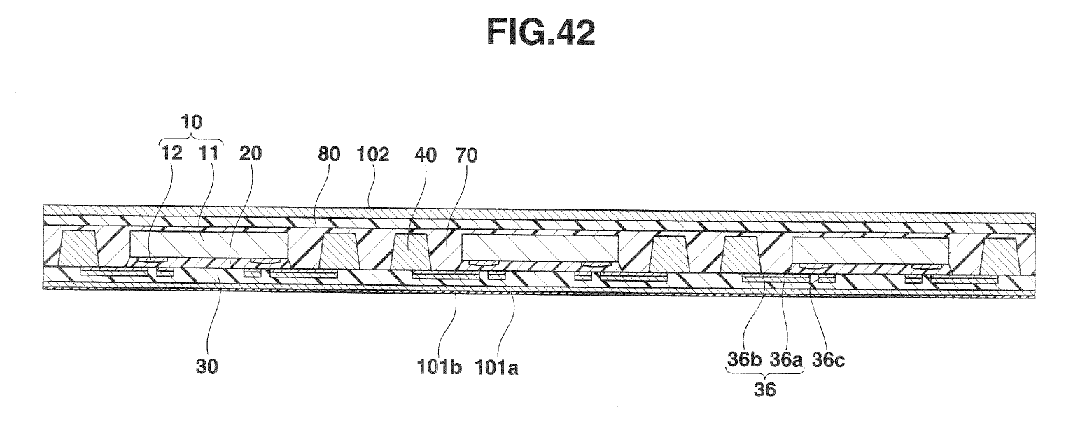

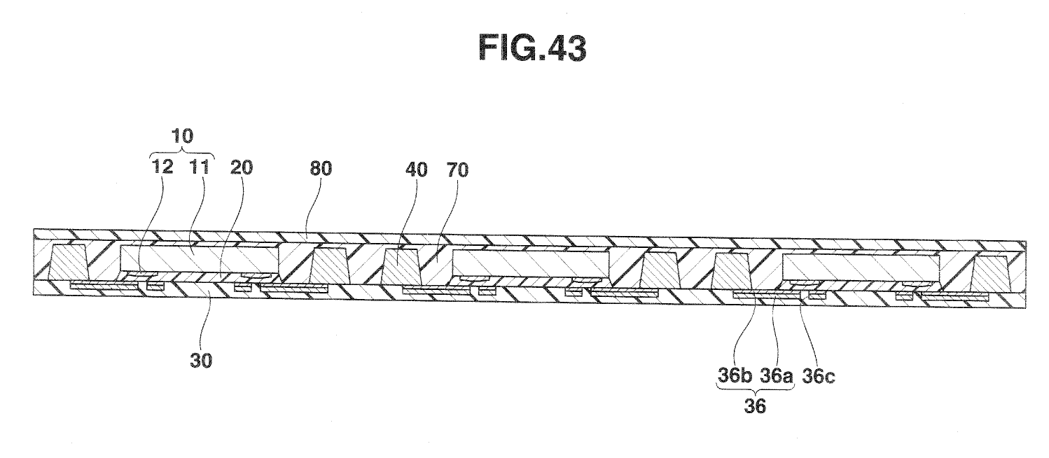

Next, as shown in FIG. 42, the carrier metal plate 101c of the first base material 101A is pealed. Thereafter, as shown in FIG. 43, the remained release layer 101b, the copper foil 101a and the second base plate 102 are removed by etching (for example, by chemical etching or wet etching). In such way, by removing the carrier metal plate 101c by pealing, the etching process can be shortened.

Here, the pealable copper foil plate may be used for the second base plate 102.

### <Modification 4>

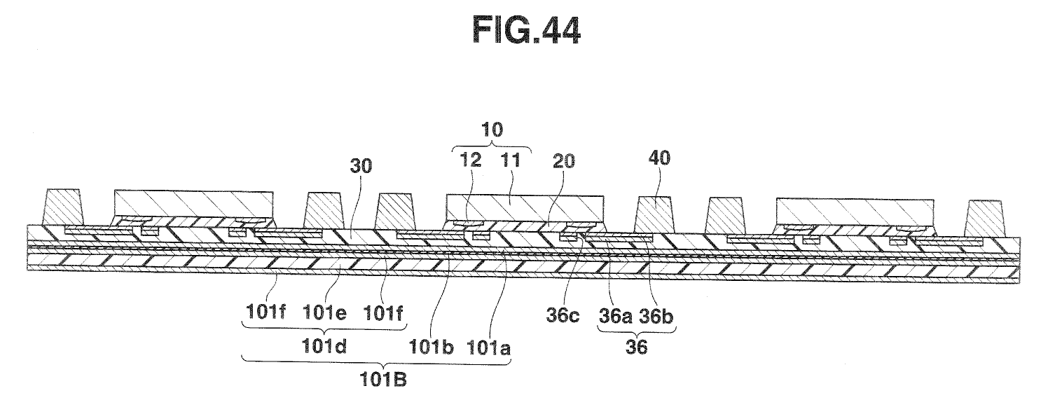

Moreover, instead of the carrier metal plate 101c, an existing substrate material 101d in which copper foils 101f and 101f are formed on the both sides of the resin layer 101e as shown in FIGS. 44 to 46 may be used.

In a case where the first base material 101B in which the existing substrate material 101d is used is to be used, the first insulating film 30 is formed on the surface in which the copper foil 101a is formed, the adhesive resin layer 20 is applied on the first insulating film 30 and the semiconductor constituents 10 are disposed on the adhesive resin layer 20 by face down bonding in a state where the electrodes 12 are disposed above the through holes 36c as shown in FIG. 44.

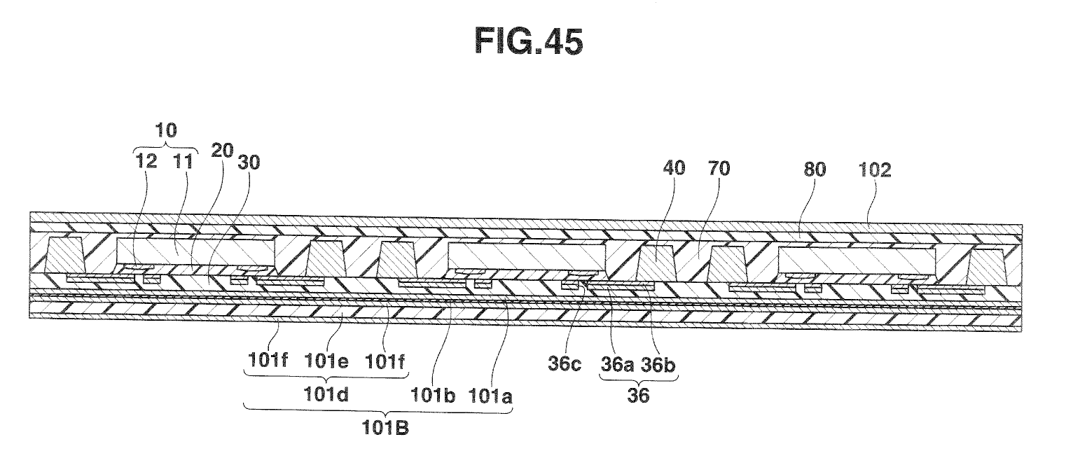

Next, a preparation is carried out by forming the second insulating film 80 on one surface of the second base plate 102 which is formed of metal, and also, the heat-curable resin sheets 70a are prepared. Then, the heat-curable sheets 70a are placed on the projection electrodes 40 and the second base plate 102 is placed on the heat-curable resin sheets 70a and the semiconductor constituents 10 in a state where the second insulating film 80 side facing downward. Further, by hot pressing the above laminated body, the sealing film 70 for encapsulating the semiconductor constituents 10 and the adhesive resin layer 20 is formed as shown in FIG. 45.

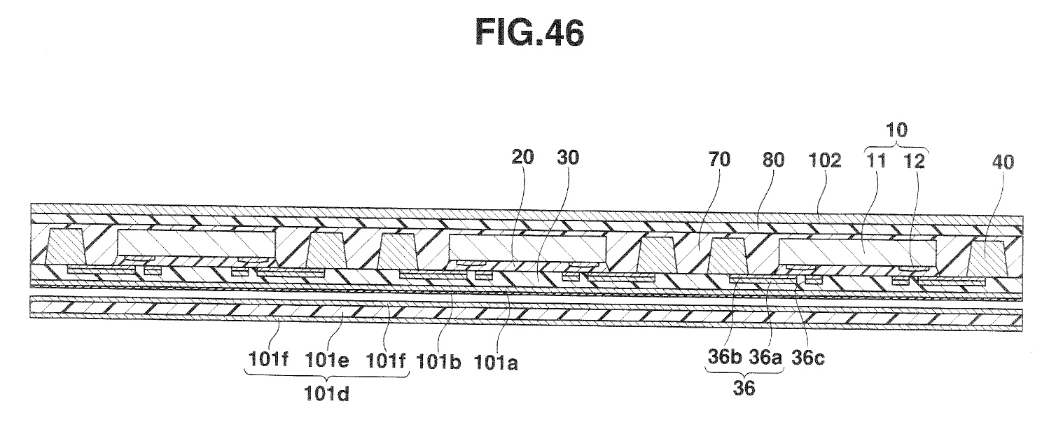

Next, as shown in FIG. 46, the substrate material 101d of the first base material 101B is pealed. Thereafter, similarly to FIG. 43, the remained release layer 101b, the copper foil 101a and the second base plate 102 are removed by etching (for example, by chemical etching or wet etching). In such way, in the embodiment, the semiconductor device can also be manufactured by the similar process as the modification 3. By using the existing substrate material 101d, there is an advantage that high consistency with the existing manufacturing line can be obtained.

Here, a similar substrate material may be used for the second base plate 102.

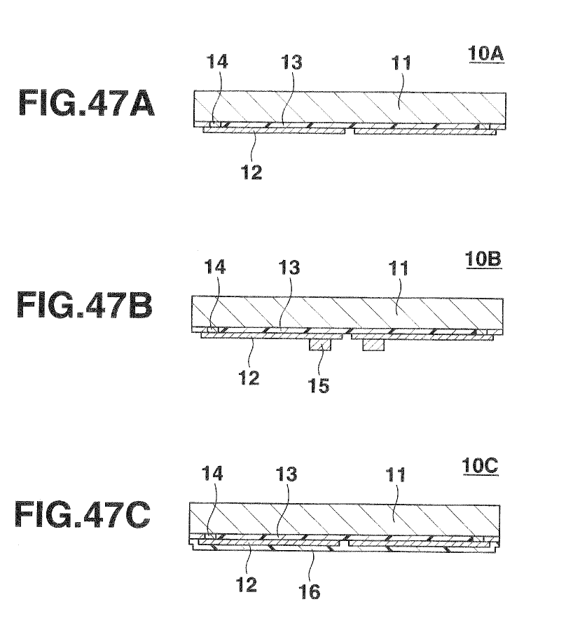

Moreover, in the above described embodiment, the semiconductor constituent 10 before being encapsulated may have a form of any one of FIGS. 47A to 47C.

That is, as shown in FIG. 47A, the semiconductor constituent 10A may be structured by forming the insulating film 13 on the under surface of the semiconductor chip 11 and by forming the via holes 14 in the insulating film 13, and may be formed in a shape where the via holes 14 are filled with a portion of the electrodes 12. As for the insulating film 13, an inorganic insulating layer (for example, a silicon oxide layer or a silicon nitride layer) or a resin insulating layer (for example, a polyimid resin layer) or the laminated body thereof is used. In a case where the insulating film 13 is the laminated body, the inorganic insulating layer may be formed on the under surface of the semiconductor chip 11 and the resin insulating layer may be formed on the surface of the inorganic insulating layer, or vice versa.

Furthermore, as shown in FIG. 47B, the semiconductor constituent 103 may be in a form where the projection electrodes 15 are provided on the electrodes 12 so as to protrude, for example.

Alternatively, as shown in FIG. 47C, the semiconductor constituent 10C may be in a form where the cover coat 16 for covering the electrodes 12 and the insulating film 13 is formed. Further, even in a case where the projection electrodes 15 are formed as in FIG. 47B, the electrodes 12 and the insulating film 13 may be covered with the cover coat 16 as shown in FIG. 47C. In such case, the projection electrodes 15 may be covered with the cover coat 16 or may not be covered with the cover coat 16.

The present U.S. patent application claims a priority under the Paris Convention of Japanese paten application No. 2009-157795 filed on Jul. 2, 2009, which shall be a basis of correction of an incorrect translation.

1. A semiconductor device, comprising:
a semiconductor chip including an electrode;
a projection electrode;
an sealing film for encapsulating the semiconductor chip and the projection electrode;
a first wiring lines provided on one surface of the sealing film, which is electrically connected with the electrode and the projection electrode;
a second wiring lines provided on the other surface of the sealing film, which is electrically connected with the projection electrode; and
at least one of a first via hole conductor for electrically connecting the first wiring lines and the projection electrode or a second via hole conductor for electrically connecting the second wiring lines and the projection electrode, wherein
an area of the projection electrode in an interface where the projection electrode and the first via hole conductor contact each other is greater than an area of the first via hole conductor in the interface and an area of the projection electrode in an interface where the projection electrode and the second via hole conductor contact each other is greater than an area of the second via hole conductor in the interface.

2. The semiconductor device according to claim 1, comprising:
a first insulating film provided between the sealing film and the first wiring lines; and
a second insulating film provided between the sealing film and the second wiring lines.

3. The semiconductor device according to claim 2, wherein the first wiring lines is embedded in a surface of the first insulating film in which the semiconductor chip is fixed.

4. The semiconductor device according to claim 3, wherein a through hole is provided in the first wiring lines at a position where the electrode of the semiconductor chip is to be disposed.

5. The semiconductor device according to claim 3, wherein a through hole is provided in the first wiring lines at a position where the projection electrode is to be disposed.

6. The semiconductor device according to claim 1, wherein the second wiring lines is embedded in a surface of the second insulating film in which the semiconductor chip is fixed.

7. The semiconductor device according to claim 6, wherein a through hole is provided in the second wiring lines at a position where the projection electrode is to be disposed.

8. A manufacturing method of a semiconductor device, comprising:
encapsulating a semiconductor chip including an electrode and a projection electrode by an sealing film;
forming a first wiring lines on one surface of the sealing film, which is electrically connected with the electrode;
forming a second wiring lines on the other surface of the sealing film; and
electrically connecting the first wiring lines and the second wiring lines by the projection electrode.

9. The manufacturing method of the semiconductor device according to claim 8, wherein the semiconductor chip and the projection electrode are formed on a first insulating film.

10. The manufacturing method of the semiconductor device according to claim 9, comprising:
forming the first insulating film and a conductor layer on a first base plate;
forming a second insulating film on a second base plate;
forming the projection electrode by patterning the conductor layer;
attaching the semiconductor chip on a surface of the first insulating film in which the projection electrode is formed;
integrally molding by disposing a heat-curable resin sheet at an upper portion of the projection electrode and by disposing the second insulating film and the second base plate at upper portions of the heat-curable resin sheet and the semiconductor chip;
removing the first base plate and the second base plate;
forming via holes in the projection electrode and in the electrode of the semiconductor chip from the first insulating film side and forming via holes from the second insulating film side; and
patterning the first wiring lines and the second wiring lines on the first insulating film and the second insulating film, respectively.

11. The manufacturing method of the semiconductor device according to claim 10, wherein the forming the first insulating film and the conductor layer on the first base plate includes integrally forming an embedded wiring lines to be embedded in the first insulating film with the first insulating film after patterning the embedded wiring lines on the conductor layer.

12. The manufacturing method of the semiconductor device according to claim 10, comprising:
integrally molding the second insulating film and the conductor layer by laminating the conductor layer after forming the second insulating film on the second base plate; and
disposing the heat-curable resin sheet at the upper portion of the projection electrode and disposing the heat-curable resin sheet between the semiconductor chips at an upper portion of the first insulating film.

13. The manufacturing method of the semiconductor device according to claim 12, wherein the integrally molding the second insulating film and the conductor layer by laminating the conductor layer after forming the second insulating film on the second base plate includes integrally molding an embedded wiring lines which is to be embedded in the second insulating film and the second insulating film after patterning the embedded wiring lines on the conductor layer.

14. The manufacturing method of the semiconductor device according to claim 11, wherein a through hole is provided in the embedded wiring lines and the via holes are formed by irradiating a laser beam to the through hole.

15. The manufacturing method of the semiconductor device according to claim 10, wherein the first base plate or the second base plate is formed by forming a release layer and a metal foil in order on an upper surface of a carrier plate and the release layer and the metal foil are removed after pealing the carrier plate.

16. The manufacturing method of the semiconductor device according to claim 15, wherein the carrier plate is formed by forming the metal foil on both surfaces of a resin layer.

17. The semiconductor device according to claim 4, wherein a through hole is provided in the first wiring lines at a position where the projection electrode is to be disposed.

18. The manufacturing method of the semiconductor device according to claim 13, wherein a through hole is provided in the embedded wiring lines and the via holes are formed by irradiating a laser beam to the through hole.
